(19) United States
(12) Patent Application Publication
(10) Pub. No.: US 2016/0294371 A1
(43) Pub. Date: Oct. 6, 2016

(54) Bit-Capture Latch with Transparency Option

(71) Applicant: Dialog Semiconductor (UK) Limited, Reading (GB)

(72) Inventor: Billy Tomatsopoulos, Swindon (GB)

(21) Appl. No.: 14/677,366

(22) Filed: Apr. 2, 2015

(51) Int. Cl. H03K 3/037; H03K 3/356

(52) U.S. Cl. CPC H03K 3/037; H03K 3/356104

(57) ABSTRACT

A novel and simple way is presented to implement a zero-capture latch circuit comprising a pair of OR AND Invert gates connected to achieve a zero-capture latch with transparency option, the output of said zero-capture latch configured to latch the input and store a zero, in functional mode, and a buffered version of the input, in test mode. A one-capture latch circuit comprising a pair of AND OR Invert gates connected to achieve a one-capture latch with transparency option, the output of said one-capture latch configured to latch the input and store a one, in functional mode, and a buffered version of the input, in test mode, is also presented. The need for a test multiplexer is eliminated, reducing the area, complexity and propagation delay of the latch circuit. The propagation delay remains constant, regardless of the mode of operation is functional or test.

### FIELD

The present disclosure relates generally to sequential logic design and more specifically to digital circuits and latches.

### BACKGROUND

Conventional SR (set-reset) latches are widely used everywhere due to their simplicity. SR latches can be constructed using OAI (OR AND Invert) and AOI (AND OR Invert) gates ultimately achieving the same or similar functions. Such latches and their variants can be modified and used as zero or one capturers, which find use, for example, in threshold detectors. The latter consist of a comparator which compares a fixed reference (threshold) with a varying input and normally trips once when the input crosses the threshold and latches a zero (or one) at its output until its set to one (or reset to zero) again. Testing a threshold detector (or any comparator with a latched output) as a continuous comparator requires the latch to be disabled. This can be achieved in a number of ways, usually interfering with the analogue operation and internal nodes of the comparator.

U.S. Pat. No. 7,225,419 (Behnen, et al.) describes a method that includes the steps of (1) receiving a circuit design having a plurality of latches; and (2) allowing one or more latches of the circuit design to be locally treated as exhibiting latch transparency during modeling of the timing behavior of the circuit design. Numerous other aspects are provided.

U.S. Pat. No. 5,319,254 (Goetting) shows a latch that may be formed as a two-part structure, one part for data input and one part for feeding back the data to form the latch. A clock signal controls whether data from a data input terminal will be forwarded to the output or whether the output signal will be provided as input and forwarded, thus forming the latch. A problem called the static ones hazard, namely registering a logical 0 when data input is logical 1, can occur with a latch of this logic structure when the circuit is entering the latch mode. This static ones hazard is avoided by controlling trip points in the gates of the cell and input buffers of the cell so that the cell implements a make-before-break transition.

U.S. Pat. No. 7,010,713 (Roth, et al.) describes a synchronization circuit for re-synchronizing data from an input clock to an output clock. The first transparent latch receives data synchronized to an input clock. A second transparent latch receives data from the first transparent latch and outputs data dependent on a delayed output clock, which is the output clock delayed by an insertion delay. An output latch receives data from the second transparent latch and synchronizes data to the output clock.

### SUMMARY

Accordingly, it is an object of one or more embodiments of the present disclosure to provide a novel, low complexity, zero-capture latch using two OAIs with feedback, configured in such a way to include a transparency option, which enables the input to propagate to the output for testing purposes.

It is a further object of one or more embodiments of the disclosure to provide a similar approach for a one-capture latch with transparency option using inverted logic.

Other objects will appear hereinafter.

The above and other objects of the present disclosure may be accomplished in the following manner. A zero-capture latch circuit comprises a pair of OR AND Invert gates connected to achieve a zero-capture latch with transparency option, the output of said zero-capture latch configured to latch the input and store a zero, in functional mode, and a buffered version of the input, in test mode. A one-capture latch circuit comprises a pair of AND OR Invert gates connected to achieve a one-capture latch with transparency option, the output of said one-capture latch configured to latch the input and store a one, in functional mode, and a buffered version of the input, in test mode.

### BRIEF DESCRIPTION OF THE DRAWINGS

The present disclosure will be more clearly understood from the following description taken in conjunction with the accompanying drawings in which like reference numerals designate similar or corresponding elements, regions and portions and in which:

FIG. 1 shows a combination of an OR and an NAND gate to construct a single OAI based latch, a structure of the prior art.

FIG. 2 illustrates a combination of two OAIs connected to achieve a zero-capture latch with transparency option, in a first preferred embodiment of the present disclosure.

FIG. 3 shows three functionally equivalent circuits, at the transistor level, which can be used to realize an OAI based latch, a structure of the prior art.

FIG. 4 illustrates a zero-capture latch with transparency, at the transistor level, in a first preferred embodiment of the present disclosure.

FIG. 5 shows an additional circuit, at the transistor level, which can be used to realize an OAI based latch, a structure of the prior art.

FIG. 6 illustrates a zero-capture latch with transparency, at the transistor level, in an alternative implementation of a first preferred embodiment of the present disclosure.

FIG. 7 shows a combination of an AND and a NOR gate to construct a single AOI based latch, a structure of the prior art.

FIG. 8 illustrates a combination of two AOIs connected to achieve a one-capture latch with transparency option, in a first preferred embodiment of the present disclosure.

FIG. 9 shows three functionally equivalent circuits, at the transistor level, which can be used to realize an AOI based latch, a structure of the prior art.

FIG. 10 illustrates a one-capture latch with transparency, at the transistor-level, in a first preferred embodiment of the present disclosure.

FIG. 11 shows an additional circuit, at the transistor level, which can be used to realize an AOI based latch, a structure of the prior art.

FIG. 12 illustrates a one-capture latch with transparency, at the transistor level, in an alternative implementation of a first preferred embodiment of the present disclosure.

FIG. 13 shows a threshold comparator circuit, in an implementation of a first preferred embodiment of the present disclosure.

### DESCRIPTION

The proposed all digital zero-capture latch features the option to become transparent in order to access the output of any preceding continuous comparator for testing purposes. The latch features minimal propagation delay between input and output, which is constant regardless of mode of operation, functional or test. A similar approach can be used for a one-capture latch, with transparency option, using inverted logic.

FIG. 1 shows a combination of OR gate 111 and NAND gate 112 to construct a single OAI based latch 110, a structure of the prior art. OR gate 111 of this two level logic cell has inputs A and B, and its output is input to NAND gate 112, which has an additional input C. The OAI latch performs an OR operation, followed by an AND operation, and an inversion at output Z.

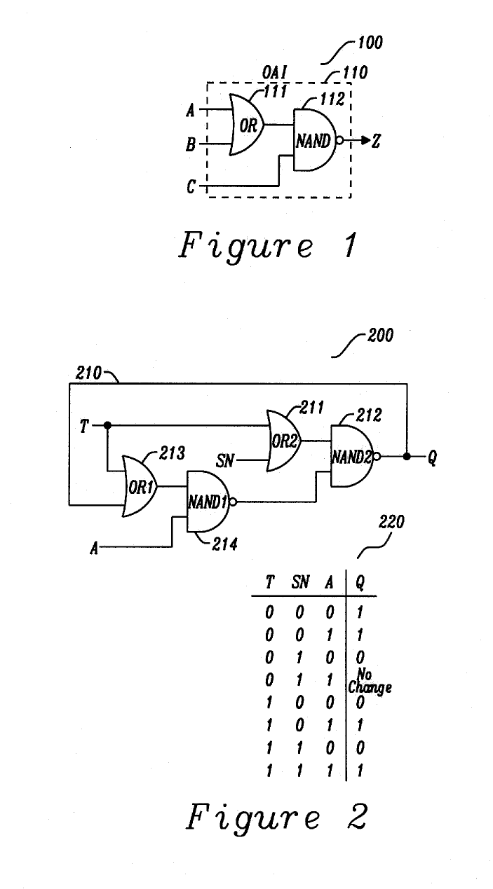

FIG. 2 illustrates a combination of two OAIs connected to achieve a zero-capture latch with transparency option, in a first preferred embodiment of the present disclosure. A block diagram of zero-capture latch 210 and its truth table 220 are shown. Zero-capture latch 210 comprises OR2 gate 211 and NAND2 gate 212, with OR2 gate 211 having inputs T and SN, and its output is input to NAND2 gate 212. NAND2 gate 212 has an additional input, the output of NAND1 gate 214. NAND1 gate 214 has inputs A and the output of OR1 gate 213. OR1 gate 213 has inputs T and Q, output of NAND2 gate 212.

If inputs T and SN are both zero in OR2 gate 211, output Q of NAND2 gate 212 is set high. Output Q is ready to latch input A of NAND1 gate 214 and store a zero when input SN is high, in functional mode. If input T is high in OR2 gate 211 and OR1 gate 213, output Q of NAND2 gate 212 is a buffered version of input A, in test mode.

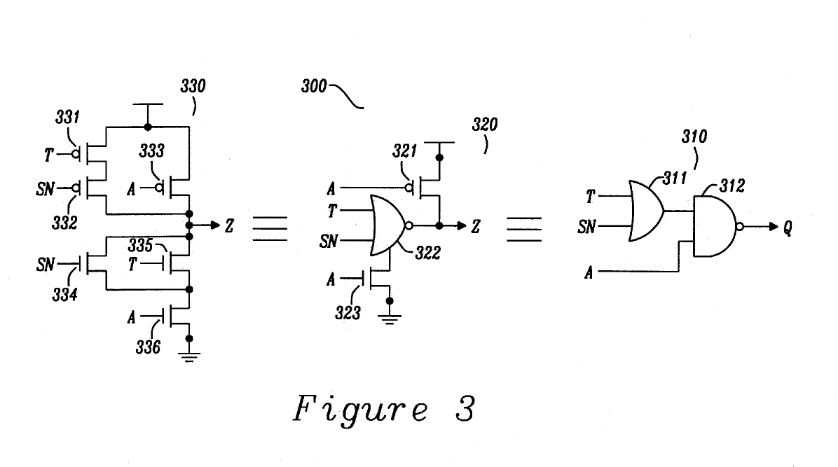

FIG. 3 shows three functionally equivalent circuits, at the transistor level, which may be used to realize an OAI based latch, a structure of the prior art. FIG. 3 shows a combination of OR gate 311 and NAND gate 312 to construct a single OAI based latch 310. The OR gate 311 has inputs T and SN, and its output is input to NAND gate 312, which has an additional input A. The OAI latch performs an OR operation, followed by an AND operation, and an inversion at output Z. If either or both input T and SN of OR gate 311 are one, and input A is zero, output Z is set high. If either but not both input T and SN of OR gate 311 are one, and input A is one, output Z is set high. If inputs T and SN of OR gate 311 are both zero, output Z is set high. Output Z is zero only when inputs T, SN, and A are all one.

The OAI based latch 320 may be constructed with PMOS transistor 321, NMOS transistor 323, and a floating ground NOR gate 322. The NOR gate 322 has inputs T and SN, and its output is Z. Transistor 321 has the input A at its gate, and its drain is output Z. Transistor 323 has input A at its gate, and its drain at the source of inputs T and SN of NOR gate 322.

The OAI based latch 330 may be constructed with PMOS transistors 331, 332, 333, and NMOS transistors 334, 335, and 336. Transistor 331 has input T at its gate, and its drain at the source of transistor 332. Transistor 332 has input SN at its gate, and its drain is output Z. Transistor 333 has input A at its gate, and its drain is also output Z. Transistor 334 has its drain at output Z, input SN at its gate, and its source at the drain of transistor 336. Transistor 335 has its drain at output Z; input T at its gate, and its source also at the drain of transistor 336. Transistor 336 has input A at its gate. Transistors 331, 332, 334, and 335 comprise the floating ground NOR gate 322 of OAI 320.

With a negative voltage applied to input A (input A is low), transistor 321 (and 333) turns on and transistor 323 (and 336) turn off. With a positive voltage applied to input A (input A is high), transistor 321 (and 333) turn off and transistor 323 (and 336) turn on. In this configuration, the OAI latch performs an OR operation between its inputs T and SN, followed by an inversion at output Z.

FIG. 4 illustrates a zero-capture latch with transparency, at the transistor level, in a first preferred embodiment of the present disclosure. The zero-capture latch may be constructed with a combination of two OAI gates, the first OAI gate comprising PMOS transistors 401, 403, and 404, and NMOS transistors 407, 408, and 411, and the second OAI gate comprising PMOS transistors 402, 405, and 406, and NMOS transistors 409, 410, and 412.

Transistor 401, of the first OAI gate, has the input T at its gate, and its drain is the source of transistor 403. Transistor 403 has output Q at its gate and its drain is the drain of transistors 407 and 408. Transistor 404 has input A at its gate, and its drain is also the drain of transistors 407 and 408. Transistor 407 has output Q at its gate and its source is the drain of transistor 411. Transistor 408 has input T at its gate and its source is also the drain of transistor 411. Transistor 411 has input A at its gate.

Transistor 402, of the second OAI gate, has input T at its gate, and its drain is the source of transistor 405. Transistor 405 has input SN at its gate and its drain is the drain of transistors 409 and 410, as well as output Q. Transistor 406 has the drain of transistors 407 and 408 at its gate, and its drain is the drain of transistors 409 and 410, as well as output Q. Transistor 409 has input SN at its gate and its source is the drain of transistor 412. Transistor 410 has input T at its gate and its source is also the drain of transistor 412. Transistor 412 has the drain of transistors 407 and 408 at its gate.

OAI gates are particularly advantaged in that the total number of transistors is less than if the OR, AND, and inverse functions are implemented separately. This results in increased speed, reduced power, smaller area, and potentially lower fabrication cost. OAI gates may be readily implemented in CMOS circuitry, but note that there are many different switching devices that could be used in such an application, such as bipolar transistors, or alternative MOS structures such as all NMOS, all PMOS, LDMOS, and the like.

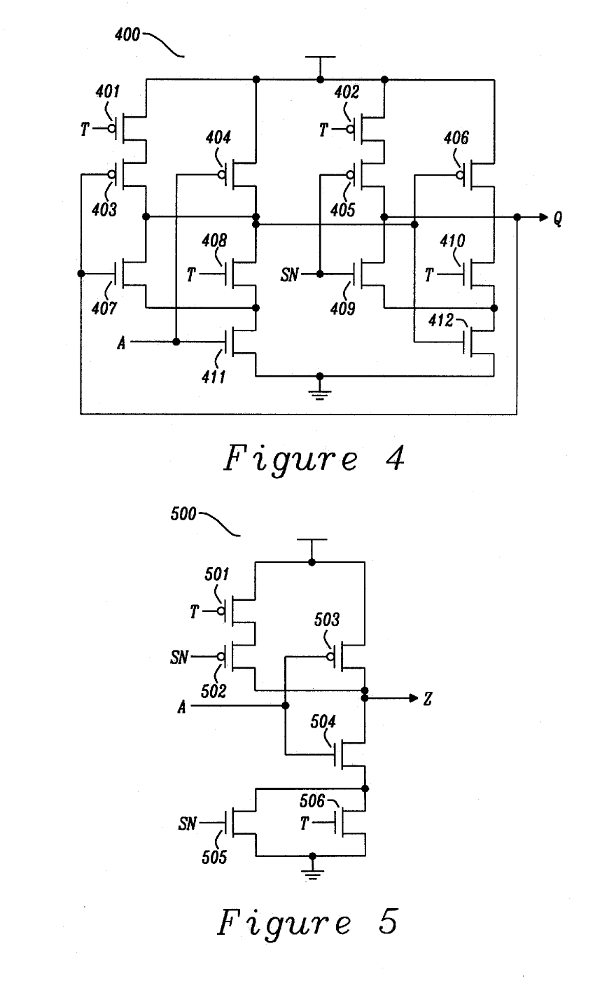

FIG. 5 shows an additional circuit, at the transistor level, which can be used to realize an OAI based latch, a structure of the prior art. The OAI based latch 500 may be constructed with PMOS transistors 501, 502, and 503, and NMOS transistors 504, 505, and 506. Transistor 501 has the input T at its gate, and its drain at the source of transistor 502. Transistor 502 has the input SN at its gate, and its drain is output Z. Transistor 503 has input A at its gate, and its drain is also output Z. Transistor 504 has its drain at output Z, input A at its gate, and its source at the drain of transistors 505 and 506. Transistor 505 has input SN at its gate. Transistor 506 has input T at its gate.

With a negative voltage applied to input A (input A is low), transistor 503 turns on and transistor 504 turns off. With a positive voltage applied to input A (input A is high), transistor 503 turns off and transistor 504 turns on. In this configuration, the OAI latch performs an OR operation between inputs T and SN, followed by an inversion at output Z.

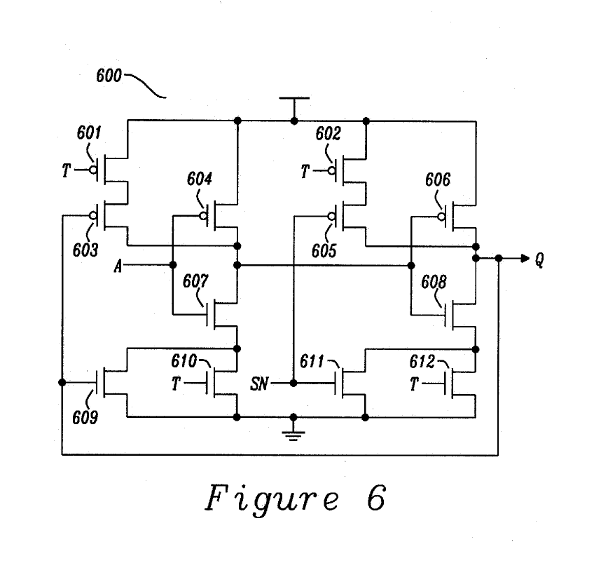

FIG. 6 illustrates a zero capture latch with transparency, at the transistor level, in an alternative implementation of a first preferred embodiment of the present disclosure. The zero capture latch may be constructed with a combination of two OAI gates, the first OAI gate comprising PMOS transistors 601, 603, and 604, and NMOS transistors 607, 609, and 610, and the second OAI gate comprising PMOS transistors 602, 605, and 606, and NMOS transistors 608, 611, and 612.

Transistor 601, of the first OAI gate, has input T at its gate, and its drain is the source of transistor 603. Transistor 603 has output Q at its gate and its drain is the drain of transistor 607 and the gate of transistor 608. Transistor 604 has input A at its gate, and its drain is also the drain of transistor 607 and also the gate of transistor 608. Transistor 607 has input A at its gate and its source is the drain of transistors 609 and 610. Transistor 609 has output Q at its gate. Transistor 610 has input T at its gate.

Transistor 602, of the second OAI gate, has the input T at its gate, and its drain is the source of transistor 605. Transistor 605 has input SN at its gate and its drain is the drain of transistor 608, as well as output Q. Transistor 606 has the drain of transistors 603 and 604 at its gate, and its drain is the drain of transistor 608, as well as output Q. Transistor 608 has the drain of transistors 603 and 604 at its gate and its source is the drain of transistors 611 and 612. Transistor 611 has input SN at its gate. Transistor 612 has input T at its gate.

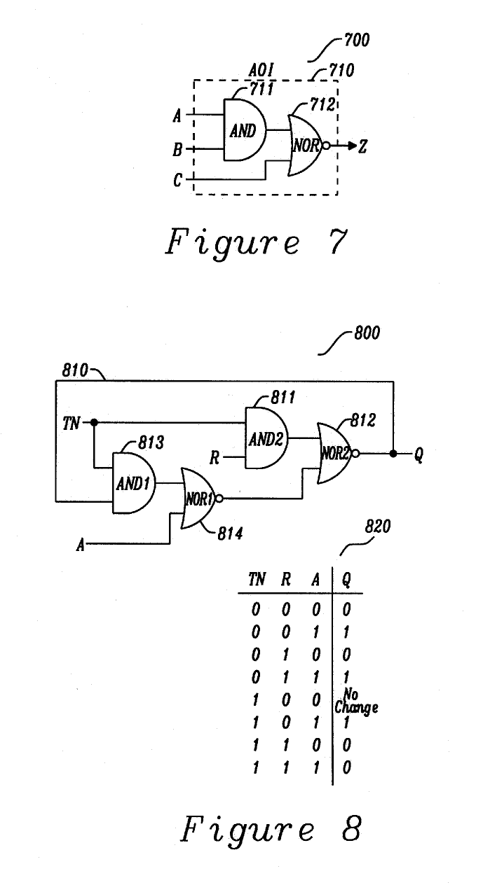

FIG. 7 shows a combination of AND gate 711 and NOR gate 712 to construct a single AOI based latch 710, a structure of the prior art. AND gate 711 of this two level logic cell has inputs A and B, and its output is input to NOR gate 712, which has an additional input C. The AOI latch performs an AND operation, followed by an OR operation, and an inversion at its output Z.

FIG. 8 illustrates a combination of two AOIs connected to achieve a one-capture latch with transparency option, in a first preferred embodiment of the present disclosure. A block diagram of one-capture latch 810 and its truth table 820 are shown. One-capture latch 810 comprises AND2 gate 811 and NOR2 gate 812, with AND2 gate 811 having inputs TN and R, and its output is input to NOR2 gate 812. NOR2 gate 812 has an additional input, the output of NOR1 gate 814. NOR1 gate 814 has inputs A and the output of AND1 gate 813. AND1 gate 813 has inputs TN and Q, output of NOR2 gate 812.

If inputs TN and R are both one in AND2 gate 811, output Q of NOR2 gate 812 is set low. Output Q is ready to latch input A of NOR1 gate 814 and store a one when input R is low, in functional mode. If input TN is low in AND2 gate 811 and AND1 gate 813, output Q of NOR2 gate 812 is a buffered version of input A, in test mode.

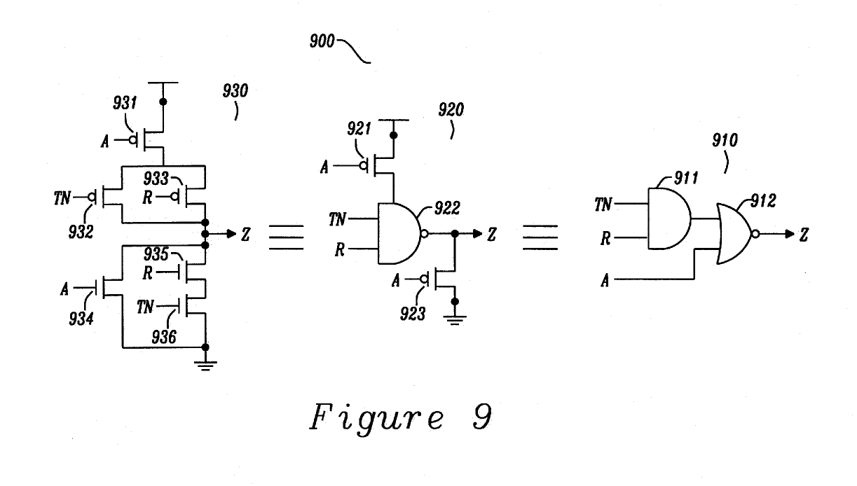

FIG. 9 shows three functionally equivalent circuits, at the transistor level, which can be used to realize an AOI based latch, a structure of the prior art. FIG. 9 shows a combination of AND gate 911 and NOR gate 912 to construct a single AOI based latch 910. The AND gate 911 has inputs TN and R, and its output is input to NOR gate 912, which has an additional input A. The AOI latch performs an AND operation, followed by an OR operation, and an inversion at output Z. If both inputs TN and R of AND gate 911 are zero, and input A is zero, output Z is set high. If either but not both input TN and R of AND gate 911 are one, and input A is zero, output Z is set high. Output Z is zero when inputs TN and R are both one and input A is zero, or when input A is one.

The AOI based latch 920 may be constructed with PMOS transistor 921, NMOS transistor 923, and a floating supply NAND gate 922. The NAND gate 922 has inputs TN and R, and its output is Z. Transistor 921 has input A at its gate, and its drain as the source of inputs TN and R of NAND gate 922. Transistor 923 has input A at its gate, and its drain at output Z.

The AOI based latch 930 may be constructed with PMOS transistors 931, 932, and 933, and NMOS transistors 934, 935, and 936. Transistor 931 has the input A at its gate, and its drain tied to the source of transistors 932 and 933. Transistor 932 has input TN at its gate, and its drain is output Z. Transistor 933 has input R at its gate, and its drain is output Z. Transistor 934 has its drain at output Z, and input A at its gate. Transistor 935 has its drain at output Z, input R at its gate, and its source at the drain of transistor 936. Transistor 936 has input TN at its gate. Transistors 932, 933, 935, and 936 comprise the floating supply NAND gate 922 of AOI 920.

With a positive voltage applied to input A (input A is high), transistor 921 (and 931) turn off and transistor 923 (and 934) turn on. With a negative voltage applied to input A (input A is low), transistor 921 (and 931) turn on and transistor 923 (and 934) turn off. In this configuration, the AOI latch performs an AND operation between inputs TN and R, followed by an inversion at output Z.

FIG. 10 illustrates a one-capture latch with transparency, at the transistor-level, in a first preferred embodiment of the present disclosure. The one-capture latch may be constructed with a combination of two AOI gates, the first AOI gate comprising PMOS transistors 1001, 1003, and 1004, and NMOS transistors 1007, 1009, and 1011, and the second AOI gate comprising PMOS transistors 1002, 1005, and 1006, and NMOS transistors 1008, 1010, and 1012.

Transistor 1001, of the first AOI gate, has the input A at its gate, and its drain is the source of transistors 1003 and 1004. Transistor 1003 has input TN at its gate and its drain is the drain of transistors 1009 and 1007. Transistor 1004 has output Q at its gate, and its drain is also the drain of transistors 1009 and 1007. Transistor 1009 has input A at its gate. Transistor 1007 has output Q at its gate and its source is the drain of transistor 1011. Transistor 1011 has input TN at its gate.

Transistor 1002, of the second AOI gate, has the drain of transistors 1009 and 1007 at its gate, and its drain is the source of transistors 1005 and 1006. Transistor 1005 has input TN at its gate and its drain is the drain of transistors 1010 and 1008, as well as output Q. Transistor 1006 has input R at its gate, and its drain is also the drain of transistors 1010 and 1008, as well as output Q. Transistor 1010 has the drain of transistors 1009 and 1007 at its gate. Transistor 1008 has input R at its gate and its source is the drain of transistor 1012. Transistor 1012 has input TN at its gate.

AOI gates are particularly advantaged in that the total number of transistors is less than if the AND, OR, and inverse functions are implemented separately. This results in increased speed, reduced power, smaller area, and potentially lower fabrication cost. AOI gates may be readily implemented in CMOS circuitry, but note that there are many different switching devices that could be used in such an application, such as bipolar transistors, or alternative MOS structures such as all NMOS, all PMOS, LDMOS, and the like.

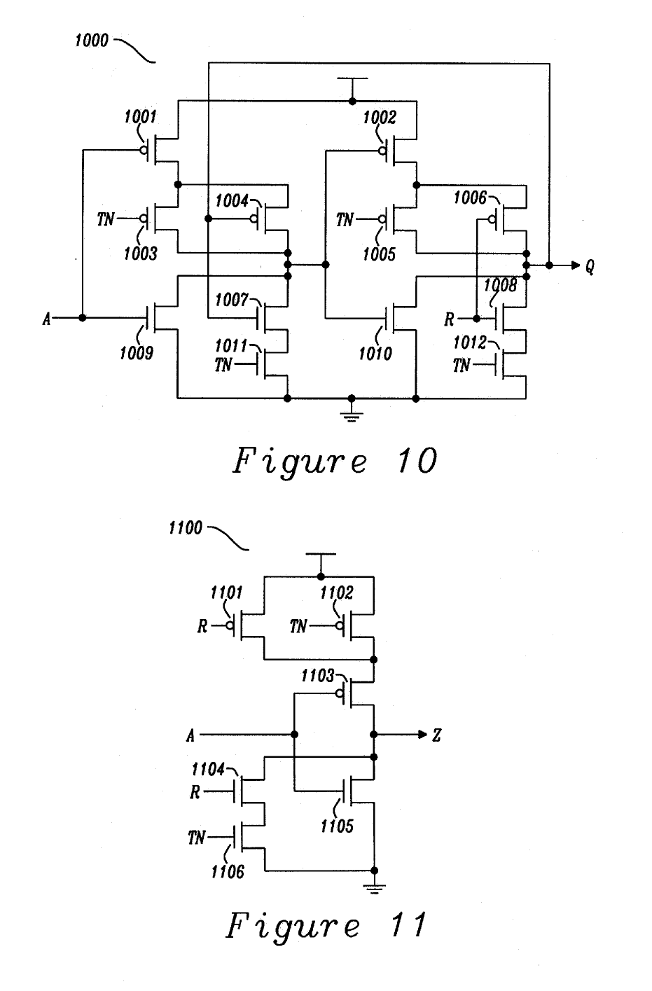

FIG. 11 shows an additional circuit, at the transistor level, which can be used to realize an AOI based latch, a structure of the prior art. The AOI based latch 1100 may be constructed with PMOS transistors 1101, 1102, and 1103, and NMOS transistors 1104, 1105, and 1106. Transistor 1101 has input R at its gate, and its drain at the source of transistor 1103. Transistor 1102 has input TN at its gate, and its drain also the source of transistor 1103. Transistor 1103 has input A at its gate, and its drain is output Z. Transistor 1104 has output Z at its drain, input R at its gate, and its source at the drain of transistor 1106. Transistor 1105 has output Z at its drain and input A at its gate. Transistor 1106 has input TN at its gate.

With a positive voltage applied to input A (input A is high), transistor 1103 turns off and transistor 1105 turns on. With a negative voltage applied to input A (input A is low), transistor 1103 turns on and transistor 1105 turns off. In this configuration, the AOI latch performs an AND operation between inputs R and TN, followed by an inversion at output Z.

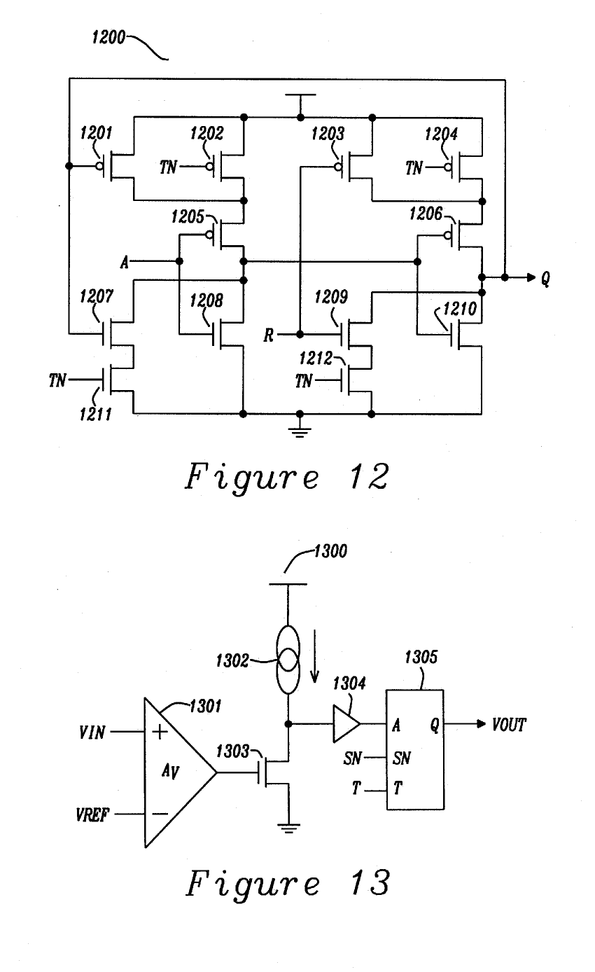

FIG. 12 illustrates a one-capture latch with transparency, at the transistor level, in an alternative implementation of a first preferred embodiment of the present disclosure. The one-capture latch may be constructed with a combination of two. AOI gates, the first AOI gate comprising PMOS transistors 1201, 1202, and 1205, and NMOS transistors 1207, 1208, and 1211, and the second AOI gate comprising PMOS transistors 1203, 1204, and 1206, and NMOS transistors 1209, 1210, and 1212.

Transistor 1201, of the first AOI gate, has output Q at its gate, and its drain is the source of transistor 1205. Transistor 1202 has input TN at its gate and its drain is also the source of transistor 1205. Transistor 1205 has input A at its gate, and its drain is the drain of transistors 1207 and 1208. Transistor 1207 has output Q at its gate and its source is the drain of transistor 1211. Transistor 1208 has input A at its gate. Transistor 1211 has input TN at its gate.

Transistor 1203, of the second AOI gate, has input R at its gate, and its drain is the source of transistor 1206. Transistor 1204 has input TN at its gate and its drain is also the source of transistor 1206. Transistor 1206 has the drain of transistor 1205 at its gate, and its drain is the drain of transistors 1209 and 1210, as well as output Q. Transistor 1209 has input R at its gate and its source is the drain of transistor 1212. Transistor 1210 has the drain of transistor 1205 at its gate. Transistor 1212 has input TN at its gate.

FIG. 13 shows a threshold comparator circuit, in an implementation of a first preferred embodiment of the present disclosure. Threshold comparator circuit 1300 may be constructed with comparator 1301, which compares fixed reference VREF to varying input VIN, and trips when input VIN crosses fixed reference VREF.

NMOS transistor 1303, of threshold comparator circuit 1300, has its gate at the output of comparator 1301, and its drain at the output of current source 1302. The output of driver 1304, of threshold comparator circuit 1300, is at input A of bit capture latch 1305 of the disclosure.

If inputs T and SN of latch 1305 are both zero, output VOUT captures a one. Output VOUT is ready to latch input A and capture a zero when input SN is high, in functional mode. If input T is high, output VOUT is a buffered version of input A, in test mode.

### Advantages

The advantages of one or more embodiments of the present disclosure include a method for a zero-capture latch with transparency option that includes the following steps: replacing the two cells of a latch and multiplexer, with a single cell, the single cell having the same propagation delay in both functional and test modes, the single cell having a small propagation delay and a small area. A similar approach can be used for a one-capture latch, with transparency option, using inverted logic.

While particular embodiments of the present disclosure have been illustrated and described, it is not intended to limit the disclosure, except as defined by the following claims.

What is claimed is:

1. A zero-capture latch circuit comprising:
a) a pair of OR AND Invert (OAI) gates connected to achieve a zero-capture latch with transparency option;
b) the output of said zero capture latch circuit configured to latch the input and store a zero, in functional mode; and
c) the output of said zero-capture latch circuit configured as a buffered version of the input, in test mode.

2. The zero-capture latch circuit of claim 1, wherein
a) each of said OAI gates comprises an OR gate and an NAND gate;
b) an output of said second OAI gate is connected to an OR gate input of said first OAI gate;
c) an output of said first OAI gate is connected to a NAND gate input of said second OAI gate;
d) a second input is common to an OR gate in both OAI gates;
e) an additional input is connected to an OR gate input of said second OAI gate;
f) an additional input is connected to a NAND gate input of said first OAI gate;
g) said OR AND Invert gate comprises a plurality of transistors.

3. The zero-capture latch circuit of claim 1, wherein said OR AND Invert gates are CMOS transistors.

4. The zero-capture latch circuit of claim 1, wherein said additional input connected to said NAND gate input of said first OAI gate is capable of providing a signal to be latched by said zero-capture latch circuit.

5. The zero-capture latch circuit of claim 1, wherein said zero-capture latch circuit is capable of the following:
a) if said second input common to said OR gate in said OAI gates and said additional input connected to said OR gate input of said second OAI gate are both zero, said output of said second OAI gate captures a one;
b) if said additional input connected to said OR gate input of said second OAI gate is one, said output of said second OAI gate captures a zero;
c) if said second input common to said OR gates in said OAI gates is one, said output of said second OAI gate is a buffered version of said additional input connected to said NAND gate input of said first OAI gate.

6. A one-capture latch circuit comprising:
a) a pair of AND OR Invert (AOI) gates connected to achieve a one-capture latch with transparency option;
b) the output of said one-capture latch circuit configured to latch the input and store a one, in functional mode; and
c) the output of said one-capture latch circuit configured as a buffered version of the input, in test mode.

7. The one-capture latch circuit of claim 6, wherein
a) each of said AOI gates comprises a NOR gate and an AND gate;
b) an output of said second AOI gate is connected to an AND gate input of said first AOI gate;
c) an output of said first AOI gate is connected to a NOR gate input of said second AOI gate;
d) a second input is common to an AND gate in both AOI gates;
e) an additional input is connected to an AND gate input of said second AOI gate;
f) an additional input is connected to a NOR gate input of said first AOI gate;
g) said AND OR Invert gate comprises a plurality of transistors.

8. The one-capture latch circuit of claim 6, wherein said AND OR Invert gates are CMOS transistors.

9. The one-capture latch circuit of claim 6, wherein said additional input connected to said NOR gate input of said first AOI gate is capable of providing a signal to be latched by said one-capture latch circuit.

10. The one-capture latch circuit of claim 6, wherein said one-capture latch circuit is capable of the following:
a) if said second input common to said AND gate in said AOI gates and said additional input connected to said AND gate input of said second AOI gate are both one, said output of said second AOI gate captures a zero;
b) if said additional input connected to said AND gate input of said second AOI gate is zero, said output of said second AOI gate captures a one;
c) if said second input common to said AND gates in said AOI gates is zero, said output of said second AOI gate is a buffered version of said additional input connected to said NOR gate input of said first AOI gate.

11. A method for forming a zero-capture latch circuit having a constant propagation delay in both functional and test modes, comprising the steps of:
a) providing a pair of OR AND Invert (OAI) gates connected to achieve a zero-capture latch with transparency option;
b) wherein the output of said zero-capture latch circuit latches the input and stores a zero, in functional mode;
c) wherein the output of said zero-capture latch circuit buffers a version of the input, in test mode;
d) capturing a one at said output of said second OAI gate if said second input common to said OR gate in said OAI gates and said additional input connected to said OR gate input of said second OAI gate are both zero;
e) capturing a zero at said output of said second OAI gate if said additional input connected to said OR gate input of said second OAI gate is one;
f) buffering a version of said additional input connected to said NAND gate input of said first OAI gate, at said output of said second OAI gate, if said second input common to said OR gates in said OAI gates is one.)

12. The method of claim 11, wherein said OR AND Invert (OAI) gates connected to achieve a zero-capture latch with transparency option provide continuous operation in both functional and test mode, reducing size and complexity of said OAI gates, resulting in a significant advance in the state of the art.

13. A method for forming a one-capture latch circuit having a constant propagation delay in both functional and test modes, comprising the steps of:
a) providing a pair of AND OR Invert (AOI) gates connected to achieve a one-capture latch with transparency option;
b) wherein the output of said one-capture latch circuit latches the input and stores a one, in functional mode;
c) wherein the output of said one-capture latch circuit buffers a version of the input, in test mode;
d) capturing a zero at said output of said second AOI gate if said second input common to said AND gate in said AOI gates and said additional input connected to said AND gate input of said second AOI gate are both one;
e) capturing a one at said output of said second AOI gate if said additional input connected to said AND gate input of said second AOI gate is zero;
f) buffering a version of said additional input connected to said NOR gate input of said first AOI gate, at said output of said second AOI gate, if said second input common to said AND gates in said AOI gates is zero.

14. The method of claim 13, wherein said AND OR Invert (AOI) gates connected to achieve a one-capture latch with transparency option provide continuous operation in both functional and test mode, reducing size and complexity of said AOI gates, resulting in a significant advance in the state of the art.

15. A threshold comparator circuit, comprising
a) a comparator which compares a fixed reference to a varying input and trips when said input crosses said fixed reference;
b) a latch which captures a zero at its output until it is set to one.
c) a latch which captures a one at its output until it is reset to zero.

16. The threshold comparator circuit of claim 15, wherein
a) said comparator has a fixed reference input and a varying input;
b) an output of said comparator is connected to a gate input of a transistor;
c) said transistor has a drain common to a current source and a driver;
d) an output of said driver is connected to a latch input;
e) an input of said latch is for data;
f) an additional input of said latch is for function or test mode selection.
